(19) United States
(12) Patent Application Publication
(10) Pub. No.: US 2013/0050919 A1
(43) Pub. Date: Feb. 28, 2013

(54) PORTABLE ELECTRONIC APPARATUS AND WATERPROOFING DEVICE

(71) Applicant: Daisuke MATSUI, Kawasaki (JP)

(72) Inventor: Daisuke MATSUI, Kawasaki (JP)

(73) Assignee: FUJITSU MOBILE COMMUNICATIONS LIMITED, Kawasaki-shi (JP)

(21) Appl. No.: 13/585,985

(22) Filed: Aug. 15, 2012

(30) Foreign Application Priority Data
Aug. 24, 2011 (JP) 2011-182088

(51) Int. Cl. H05K 7/00

(52) U.S. Cl. 361/679.01

(57) ABSTRACT

A storage portion is formed in a casing between a hole bored in the casing and a switch disposed inside an apparatus, and a waterproofing device is installed in the storage portion. The waterproofing device is composed of an elastic material, and includes a cylindrical portion with a bottom, a plunger of a key top being inserted in the cylindrical portion, a flange portion formed around the edge portion of the opening of the cylindrical portion, and waterproofing ribs protruding from both surfaces of the flange portion so as to enclose the cylindrical portion. A plate is embedded in the flange portion to support the elastic deformation of the waterproofing ribs when the waterproofing device is pushed into the storage portion, and makes the waterproofing ribs adhere to the inner wall of the storage portion by the resilience thereof. As a result, water is prevented from entering the apparatus.

### CROSS-REFERENCE TO RELATED APPLICATION

This application is based upon and claims the benefit of priority of the prior Japanese Patent Application No. 2011-182088, filed on Aug. 24, 2011, the entire contents of which are incorporated herein by reference.

### FIELD

The embodiments discussed herein are related to portable electronic apparatuses and waterproofing devices.

### BACKGROUND

Some portable electronic apparatuses are known to employ a waterproofing structure in which water is prevented from reaching switches accommodated inside casings through key tops serving as input devices disposed so as to be exposed to the outside (for example, see Japanese Laid-open Patent Publication Nos. 2006-344528 and 2009-54380). In the waterproofing structure, a waterproofing device composed of a deformable waterproofing material is disposed between a key top and a switch so that an opening formed in a casing at a position where the key top is disposed is made watertight, and the motion of the key top is transmitted to the switch via the waterproofing device when the key top is pushed.

Such a waterproofing device may include, for example, a hollow cylindrical portion with a bottom, the cylindrical portion having a rib formed on the outer circumference thereof. When the cylindrical portion is inserted in an opening, the rib is pushed against the inner wall of the opening, and is deformed by compression.

This enables the waterproofing device to exert the waterproofing effect. In this structure, when a plunger extending coaxially with a key top pushes the bottom part of the cylindrical portion in response to a key operation, the bottom part is elastically deformed to push a switch. This causes the switch to be closed. When the plunger stops pushing, the deformed bottom part recovers the original shape thereof, and the switch is opened.

Another waterproofing device may include an outer circumferential portion and a central portion serving as a plunger. The outer circumferential portion engages with a flange formed inside an opening in a casing over the entire circumference to close the opening, and the plunger transmits the motion of a key top to a switch when the key top is pushed. In this structure, when the key top is pushed down, a connecting portion between the plunger and the outer circumferential portion is elastically deformed such that the plunger pushes the switch. This causes the switch to be closed. When the plunger stops pushing, the deformed connecting portion recovers the original shape thereof, and the switch is opened.

The waterproofing device including the cylindrical portion with the rib formed on the outer circumference has a hard sleeve for preventing deformation of the cylindrical portion disposed inside the cylindrical portion. With this, only the rib is deformed by compression when the waterproofing device is pushed into the opening in the casing, and keeps stopping water. The cylindrical portion has an extendable part at a position closer to the bottom part than the sleeve, and the extendable part is elastically deformed when the plunger pushes the bottom part. This provides you with a good sense of touch when you push the key down. In addition, the opening in the casing has an allowance for insertion of the cylindrical portion. The extendable part and the insertion allowance disadvantageously prevent the size of a portable electronic apparatus into which the waterproofing device including the cylindrical portion is incorporated from being reduced in a direction along which the key top is pushed down.

In addition, the waterproofing device having the engaging part formed on the outer circumferential portion only engages with the flange of the casing, and the engaging part is not forced to adhere to the flange, resulting in insufficient watertightness.

### SUMMARY

According to one aspect, a portable electronic apparatus includes a storage portion that is formed in a casing between a switch disposed inside the apparatus and a hole formed in the casing and that has a communicating hole at a position coaxial with the hole corresponding to the switch and a waterproofing device installed in the storage portion so as to close the communicating hole. The waterproofing device includes a cylindrical portion with a bottom, the cylindrical portion being inserted in the communicating hole and a plunger of a key top that extends through the hole being inserted in the cylindrical portion, a flange portion formed around an edge portion of an opening of the cylindrical portion, and a waterproofing rib protruding from a surface of the flange portion so as to enclose the cylindrical portion.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a schematic view of an example portable electronic apparatus;

FIG. 2 is a cross-sectional view of a waterproofing key structure of a portable electronic apparatus according to a first embodiment;

FIG. 3 is a perspective view of a waterproofing device for the portable electronic apparatus according to the first embodiment viewed from a position adjacent to a key top;

FIG. 4 is a perspective view of the waterproofing device for the portable electronic apparatus according to the first embodiment viewed from a position adjacent to a switch;

FIG. 5 is a cross-sectional view of the waterproofing device for the portable electronic apparatus according to the first embodiment;

FIG. 6 illustrates the portable electronic apparatus and the waterproofing device according to the first embodiment before the waterproofing device is installed in the portable electronic apparatus;

FIG. 7 illustrates the portable electronic apparatus and the waterproofing device according to the first embodiment after the waterproofing device is installed in the portable electronic apparatus;

FIG. 8 is a cross-sectional view of a waterproofing key structure of a portable electronic apparatus according to a second embodiment; and

FIG. 9 is a cross-sectional view of a waterproofing device for the portable electronic apparatus according to the second embodiment.

### DESCRIPTION OF EMBODIMENTS

Several embodiments will be described below with reference to the accompanying drawings, wherein like reference numerals refer to like elements throughout. The embodiments may be combined without deviating from the inventive concept.

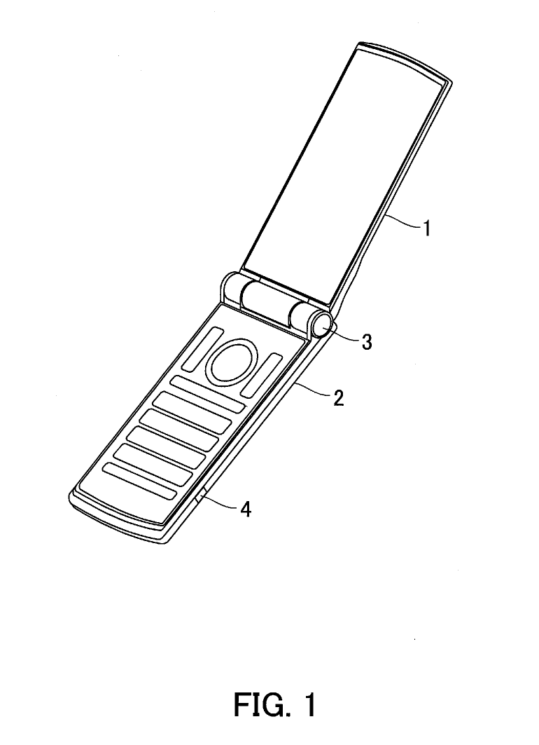

FIG. 1 is a schematic view of an example portable electronic apparatus.

The portable electronic apparatus has a large number of keys serving as input devices. For example, a flip cellular phone serving as the portable electronic apparatus includes a display unit 1, an operating unit 2, and a hinge unit 3 that connects the display unit 1 and the operating unit 2. Various keys are laid out on a surface of the operating unit 2, which faces the display unit 1 when the cellular phone is folded. The operating unit 2 has a key 4 on a side surface thereof. The key 4 herein is used less frequently or used for special application. A waterproofing key structure relating to the key 4 disposed on the side surface of the operating unit 2 will now be described with reference to the drawings.

### (a) First Embodiment

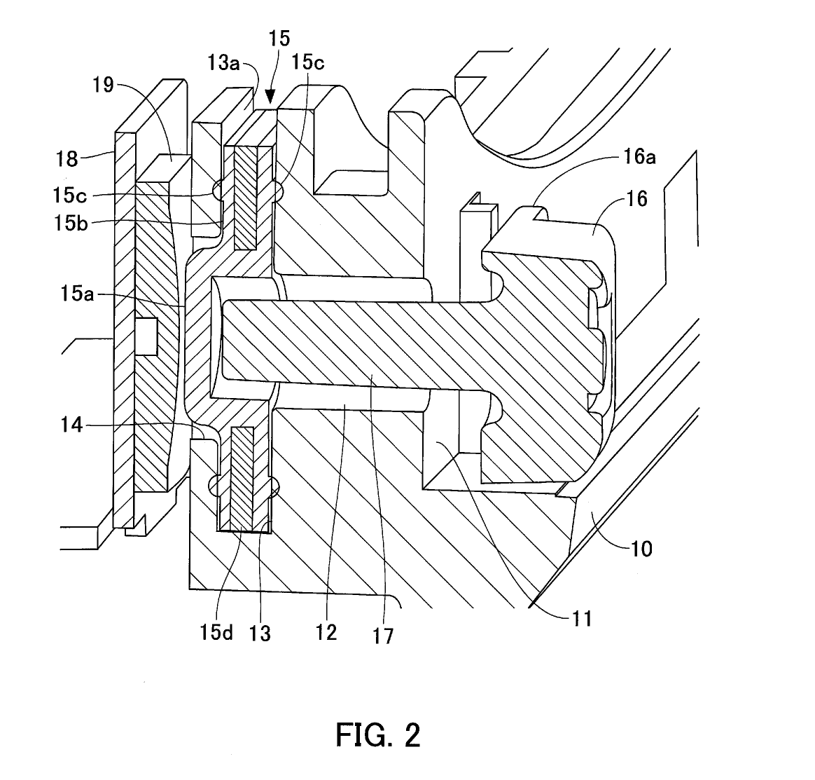

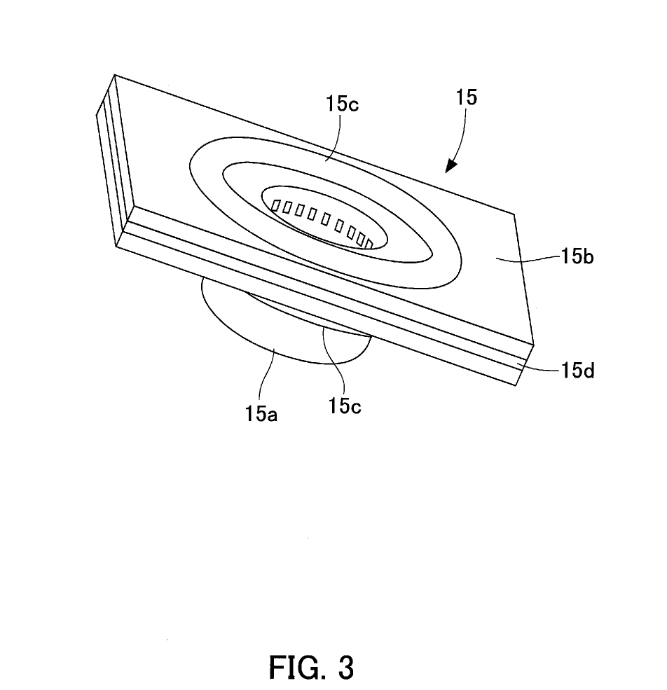

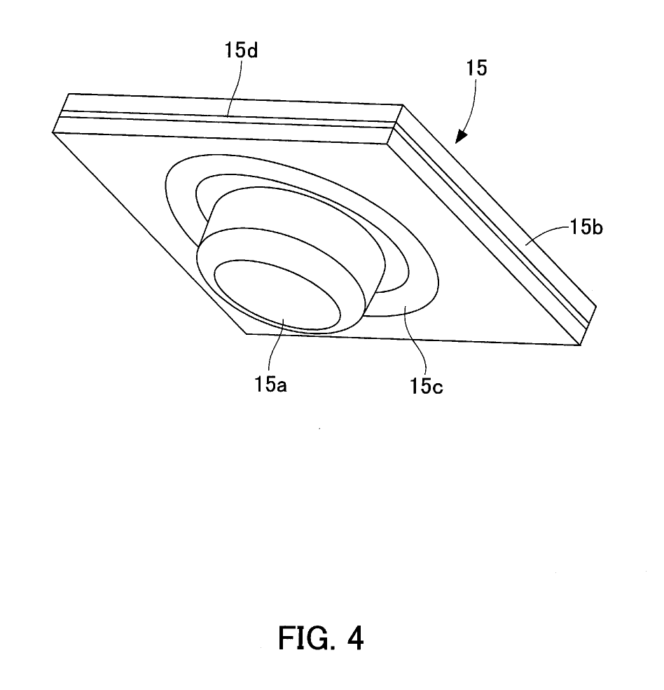

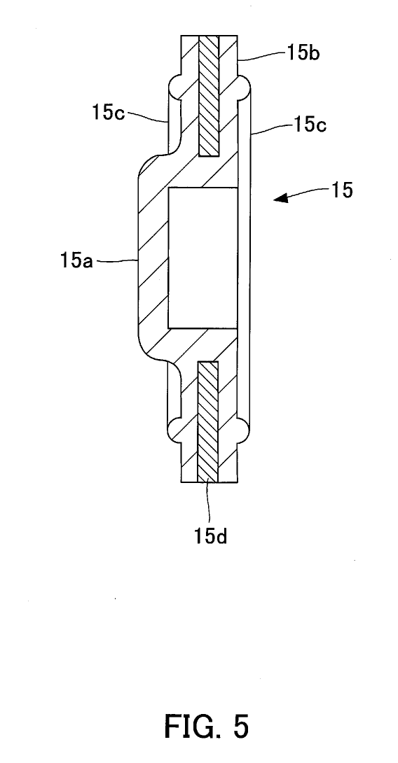

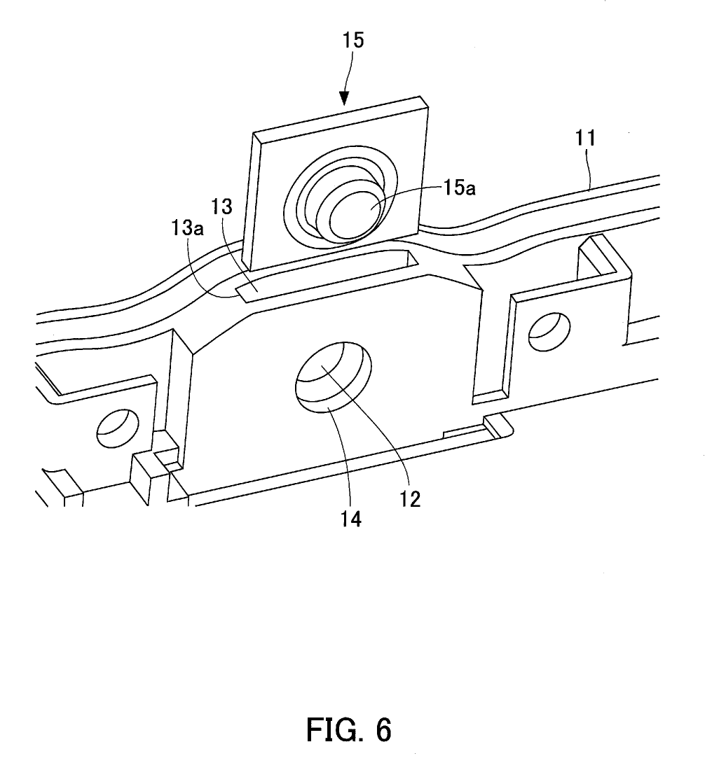

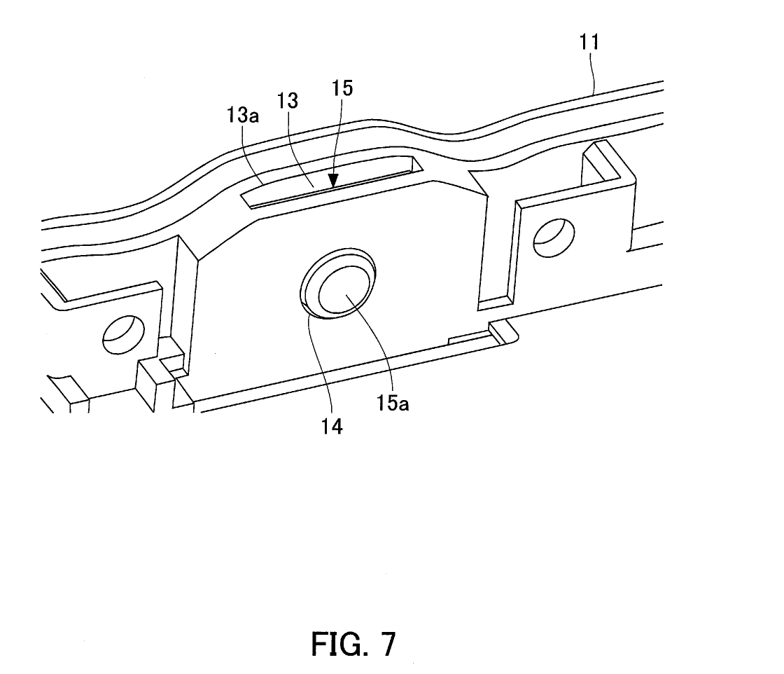

FIG. 2 is a cross-sectional view of a waterproofing key structure of a portable electronic apparatus according to a first embodiment. FIG. 3 is a perspective view of a waterproofing device for the portable electronic apparatus according to the first embodiment viewed from a position adjacent to a key top, FIG. 4 is a perspective view of the waterproofing device for the portable electronic apparatus according to the first embodiment viewed from a position adjacent to a switch, and FIG. 5 is a cross- sectional view of the waterproofing device for the portable electronic apparatus according to the first embodiment. FIG. 6 illustrates the portable electronic apparatus and the waterproofing device according to the first embodiment before the waterproofing device is installed in the portable electronic apparatus, and FIG. 7 illustrates the portable electronic apparatus and the waterproofing device according to the first embodiment after the waterproofing device is installed in the portable electronic apparatus.

As illustrated in FIG. 2, a sidewall 11 extends upward from a rear casing 10 of the operating unit 2 of the cellular phone along the side surfaces of the casing 10, and has a hole 12 bored therein. A storage portion 13 is formed adjacent to the hole 12 on the far side of the hole 12. This storage portion 13 is a pocket-shaped recess having a slender, slit-shaped entrance 13a open in a direction orthogonal to the axis of the hole 12 at an upper part of FIG. 2, and is continuously concaved from the entrance 13a in the direction orthogonal to the axis of the hole 12. The storage portion 13 has a communicating hole 14 that is coaxial with the hole 12 and that communicates with the inside of the casing 10. A waterproofing device 15 is inserted in the storage portion 13 so as to obstruct the hole 12. A plunger 17 of a key top 16 is disposed in the hole 12 so as to be reciprocable in the axial direction of the hole 12. A switch 19 mounted on a printed circuit board 18 is disposed adjacent to the storage portion 13 and coaxially with the hole 12 on a side of the storage portion 13 adjacent to the inside of the cellular phone. The key top 16 has a flanged portion 16a. The flanged portion 16a engages with a front casing (not illustrated) of the operating unit when the front casing is assembled to the casing 10 illustrated in FIG. 2, and prevents the key top 16 from dropping off.

As illustrated in FIGS. 3 to 5, the waterproofing device 15 includes a shallow, cup-shaped cylindrical portion 15a with a bottom, a square flange portion 15b formed around the edge portion of the opening of the cylindrical portion 15a, and waterproofing ribs 15c protruding from both surfaces of the flange portion 15b so as to enclose the cylindrical portion 15a. The cylindrical portion 15a, the flange portion 15b, and the waterproofing ribs 15c are composed of an elastic material such as natural rubber or silicone rubber, and are integrated with each other.

It is preferable that a plate 15d composed of a material containing metal or resin harder than that of the flange portion 15b be embedded in the flange portion 15b of the waterproofing device 15. The plate 15d is square, and has a hole bored in the central portion thereof. The diameter of the hole is close to the outside diameter of the cylindrical portion 15a. The plate 15d is integrated with the cylindrical portion 15a, the flange portion 15b, and the waterproofing ribs 15c by insert molding or coinjection molding. The embedment of the plate 15d harder than the flange portion 15b in the flange portion 15b imparts rigidity to the elastic flange portion 15b. This enables the waterproofing device 15 to be easily installed in the storage portion 13, and furthermore, enables the waterproofing ribs 15c to be supported from inside the flange portion 15b when the waterproofing ribs 15c are deformed by compression inside the storage portion 13.

As illustrated in FIG. 6, the waterproofing device 15 is inserted into the storage portion 13 from the entrance 13a such that the cylindrical portion 15a opposes the communicating hole 14. As illustrated in FIG. 2, the width of the entrance 13a in the axial direction of the hole 12 is larger than the thickness of the flange portion 15b, and is smaller than the distance between the tops of the waterproofing ribs 15c formed on both surfaces of the flange portion 15b. Accordingly, the waterproofing device 15 is pushed into the storage portion 13 as the waterproofing ribs 15c are squashed. The cylindrical portion 15a protruding from the flange portion 15b is also squashed such that the thickness thereof approximates that of the flange portion 15b when the waterproofing device 15 is pushed into the storage portion 13. When the waterproofing device 15 is disposed at a predetermined position, the cylindrical portion 15a recovers the original shape, and is inserted in the communicating hole 14 as illustrated in FIGS. 2 and 7.

In this waterproofing key structure, when a user pushes the key top 16 down, the plunger 17 extending to the inside of the cylindrical portion 15a of the waterproofing device 15 pushes the bottom part of the cylindrical portion 15a. This causes the bottom part of the cylindrical portion 15a to be elastically deformed and to push the switch 19. As a result, the switch 19 is closed. When the user stops pushing the key top 16, the elastically deformed bottom part of the cylindrical portion 15a recovers the original shape thereof, and is separated from the switch 19. As a result, the switch 19 is opened. At the same time, the bottom part of the cylindrical portion 15a pushes the plunger 17 back, and as a result returns the key top 16 to the initial position thereof.

As described above, the pocket-shaped storage portion 13 is formed in the sidewall 11 on a side of the hole 12 adjacent to the inside of the cellular phone in the axial direction, and the waterproofing device 15 is inserted into the storage portion 13 in a direction orthogonal to the axial direction. The waterproofing device 15 is easily installed in the storage portion 13 by fitting the waterproofing device 15 into the storage portion 13 from above the rear casing 10 of the operating unit 2. The waterproofing ribs 15c are squashed while the waterproofing device 15 is pushed into the storage portion 13, and adheres to the plane-parallel inner walls of the storage portion 13 due to the resilience when the waterproofing device 15 is installed in the storage portion 13. Since one of the waterproofing ribs 15c adheres to the inner wall of the storage portion 13 adjacent to the hole 12 so as to enclose the hole 12, water entering the hole 12 in the sidewall 11 is reliably prevented from entering the inside of the operating unit 2.

Since the waterproofing ribs 15c of the waterproofing device 15 formed on the flange portion 15b enable the entire cylindrical portion 15a to function as a part extendable when pushed by the plunger 17, the length of the cylindrical portion 15a does not need to be larger than that required for the extendable part in a direction along which the key is pushed down. As a result, the length of the cylindrical portion 15a in a direction along which the cylindrical portion 15a extends may be regulated to small values. This enables the key portion to be reduced in size in the direction along which the key is pushed down, and thereby enables the internal space of the operating unit 2 to be increased.

The cylindrical portion 15a of the waterproofing device 15 is not reinforced by a hard sleeve. However, the cylindrical portion 15a is not deformed inward due to the small extending length thereof, and the opening in which the plunger 17 of the key top 16 is inserted is not significantly narrowed. As a result, the plunger 17 disposed inside the cylindrical portion 15a is not caught by the cylindrical portion 15a.

### (b) Second Embodiment

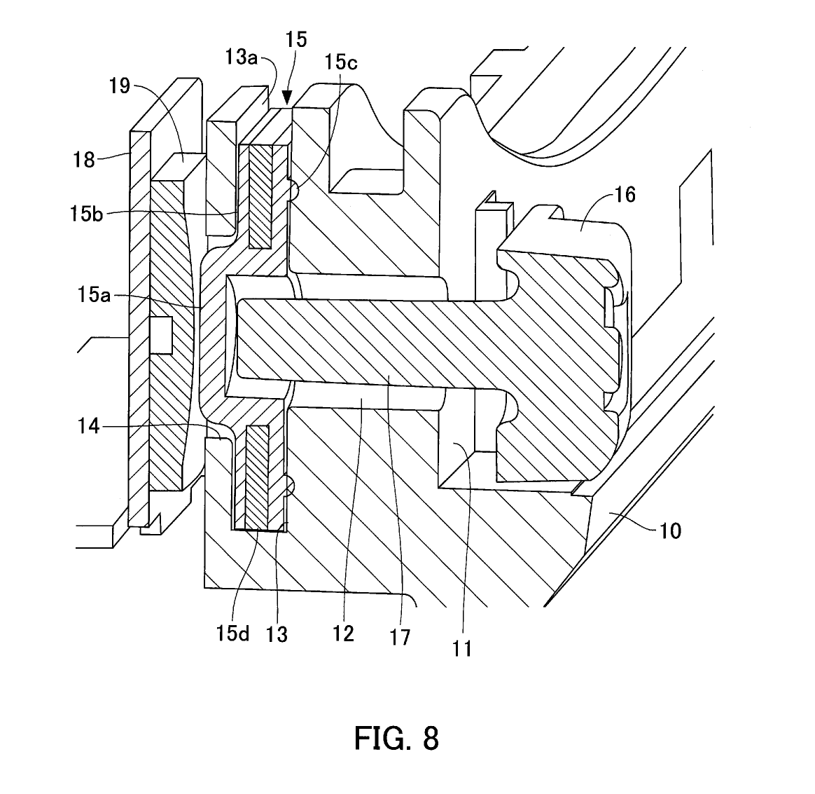

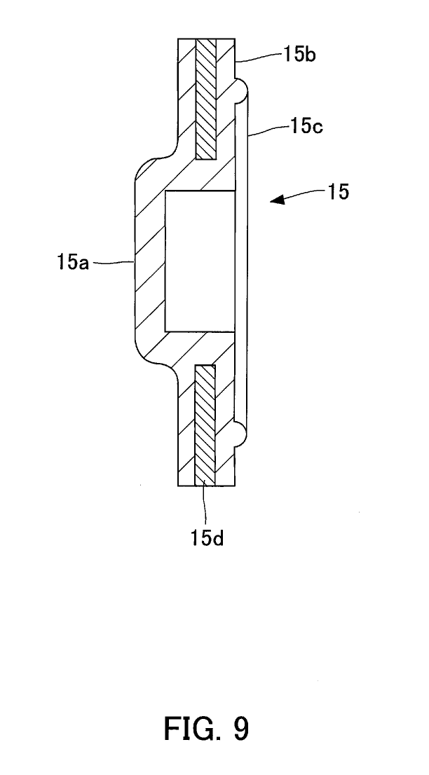

FIG. 8 is a cross-sectional view of a waterproofing key structure of a portable electronic apparatus according to a second embodiment, and FIG. 9 is a cross-sectional view of a waterproofing device for the portable electronic apparatus according to the second embodiment. In FIGS. 8 and 9, the same reference numbers and symbols are used for components the same as or equivalent to those illustrated in FIGS. 2 and 5, and the detailed descriptions will be omitted.

The waterproofing device 15 of the portable electronic apparatus according to the second embodiment has only one waterproofing rib 15c on a surface of the flange portion 15b adjacent to the opening of the cylindrical portion 15a with a bottom. This waterproofing device 15 is installed in the storage portion 13 in the same manner as that according to the first embodiment. That is, the cylindrical portion 15a is squashed such that the thickness thereof approximates that of the flange portion 15b, and the waterproofing device 15 in this state is pushed into the storage portion 13 as the waterproofing rib 15c is squashed. When the waterproofing device 15 is pushed to a predetermined position, the cylindrical portion 15a recovers the original shape thereof, and is inserted in the communicating hole 14 as illustrated in FIG. 8.

Also in this waterproofing key structure, when a user pushes the key top 16 down, the plunger 17 of the key top 16 pushes the bottom part of the cylindrical portion 15a to elastically deform the bottom part. As a result, the switch 19 is closed. When the user stops pushing the key top 16, the elastically deformed bottom part of the cylindrical portion 15a recovers the original shape thereof, and is separated from the switch 19. As a result, the switch 19 is opened, and the bottom part of the cylindrical portion 15a recovering the original shape returns the plunger 17 to the initial position thereof

Although the waterproofing device 15 according to the first and second embodiments has only one waterproofing rib 15c on the surface of the flange portion 15b adjacent to the hole 12, the waterproofing devices 15 may have one or more concentric ribs. Furthermore, although the flange portion 15b of the waterproofing device 15 is square, the shape of the flange portion 15b is not limited to this, and the flange portion 15b may be, for example, circular. In addition, although the waterproofing key structure of the portable electronic apparatus is incorporated into the key 4 disposed on the side surface of the operating unit 2 of the cellular phone in the description above, the waterproofing key structure may be incorporated into keys disposed on a surface where ten keys and the like of the operating unit 2 are disposed.

The portable electronic apparatus and the waterproofing device according to the above-described embodiments enable the key portion to be reduced in thickness, and ensure sufficient waterproof performance.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A portable electronic apparatus comprising:
a storage portion that is formed in a casing between a switch disposed inside the apparatus and a hole formed in the casing and that has a communicating hole at a position coaxial with the hole corresponding to the switch; and
a waterproofing device installed in the storage portion so as to close the communicating hole, wherein
the waterproofing device includes a cylindrical portion with a bottom, the cylindrical portion being inserted in the communicating hole and a plunger of a key top that extends through the hole being inserted in the cylindrical portion, a flange portion formed around an edge portion of an opening of the cylindrical portion, and a waterproofing rib protruding from a surface of the flange portion so as to enclose the cylindrical portion.

2. The portable electronic apparatus according to claim 1, wherein the waterproofing device includes another waterproofing rib on the other surface of the flange portion.

3. The portable electronic apparatus according to claim 1, wherein the waterproofing rib protrudes from the surface of the flange portion remote from the bottom of the cylindrical portion of the waterproofing device.

4. The portable electronic apparatus according to claim 1, wherein the storage portion is a pocket-shaped recess having an entrance open in a direction orthogonal to an axis of the hole, and is concaved from the entrance in the direction orthogonal to the axis of the hole.

5. The portable electronic apparatus according to claim 4, wherein a width of the entrance of the storage portion in an axial direction of the hole is larger than a thickness of the flange portion, and is smaller than a distance between both ends of the flange portion including a top of the waterproofing rib in a thickness direction of the flange portion.

6. The portable electronic apparatus according to claim 1, wherein a plate composed of a material harder than a material of the waterproofing device is embedded in the flange portion.

7. A waterproofing device in a portable electronic apparatus comprising:
a cylindrical portion with a bottom in which a plunger of a key top is to be inserted;
a flange portion formed around an edge portion of an opening of the cylindrical portion; and
a waterproofing rib formed on a surface of the flange portion so as to enclose the cylindrical portion.
